(19) United States
(12) Patent Application Publication
(10) Pub. No.: US 2026/0096440 A1
(43) Pub. Date: Apr. 2, 2026

(54) MULTI-CHIP MODULE WITH ADJUSTED MUTUAL INDUCTANCE FOR LNA INPUT MATCHING

(71) Applicant: Skyworks Solutions, Inc., Irvine, CA (US)

(72) Inventors: Peihua Ye, Irvine, CA (US); Shengkai Xu, Irvine, CA (US); Yong Hee Lee, Tustin, CA (US); Thomas Obkircher, Santa Ana, CA (US)

(21) Appl. No.: 19/343,931

(22) Filed: Sep. 29, 2025

Related U.S. Application Data
(60) Provisional application No. 63/701,472, filed on Sep. 30, 2024.
(60) Provisional application No. 63/701,425, filed on Sep. 30, 2024.

(51) Int. Cl. H01L 23/66; H03F 1/56

(52) U.S. Cl. CPC H10W 44/20; H03F 1/565; H03F 2200/294; H10W 44/234

(57) ABSTRACT

A multi-chip module, a packaged module and a wireless device are provided. The multi-chip module comprises a plurality of layers including a first layer, a second layer and a third layer, said second layer positioned between the first layer and third layer; a low noise amplifier circuit distributed across the plurality of layers and including a first inductor in the first layer, a second inductor in the third layer, and a transistor; a common ground plane spanning over at least a portion of the second layer; and a dielectric opening through the common ground plane, said dielectric opening located between the first inductor and the second inductor. The dielectric opening alters a mutual inductance in the low noise amplifier circuit, resulting in an improved input impedance of the low noise amplifier circuit for better input matching.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

### BACKGROUND

### Field

Embodiments of the invention relate to radio frequency (RF) electronics systems, and in particular to multi-chip modules including low noise amplifiers (LNAs).

### Description of the Related Technology

A low noise amplifier (LNA) can be used to boost the amplitude of a relatively weak radio frequency (RF) signal received via an antenna. Thereafter, the boosted RF signal can be used for a variety of purposes, including, for example, driving a switch, a mixer, and/or a filter in an RF communication system.

Examples of RF communication systems with one or more LNAs include, but are not limited to, mobile phones, tablets, base stations, network access points, customer-premises equipment (CPE), laptops, and wearable electronics.

LNAs can be included in RF communication systems to amplify signals of a wide range of frequencies. For example, an LNA can be used to provide low noise amplification to RF signals in a frequency range of about 30 kHz to 300 GHz, such as in the range of about 400 MHz to about 7.125 GHz for Frequency Range 1 (FR1) of the Fifth Generation (5G) communication standard or in the range of about 24.250 GHz to about 71.000 GHz for Frequency Range 2 (FR2) of the 5G communication standard.

Modern LNAs typically seek to achieve a low power consumption. However, such low power consumptions result in a decrease in the interrupted direct current (IDC) of an LNA, which decreases the real part of the input impedance (Zin) of the LNA. At the same time, the output impedance of an antenna or LNA pre-filter, for example, providing a signal to the LNA input will remain at a constant value such as 50 ohm. Thus impedance matching at the LNA input can prove challenging.

### SUMMARY

According to one embodiment there is provided a multi-chip module. The multi-chip module comprises: a plurality of layers including a first layer, a second layer and a third layer, said second layer positioned between the first layer and third layer; a low noise amplifier circuit distributed across the plurality of layers and including a first inductor in the first layer, a second inductor in the third layer, and a transistor; a common ground plane spanning over at least a portion of the second layer; and a dielectric opening through the common ground plane, said dielectric opening located between the first inductor and the second inductor.

In one example the first inductor is connected to a gate terminal or base terminal of the transistor.

In one example the second inductor is connected to a source terminal or emitter terminal of the transistor.

In one example the transistor is included in the first layer.

In one example the transistor is implemented within an integrated circuit in the multi-chip module.

In one example the first inductor is a surface-mount device.

In one example the second inductor is formed from a signal trace in the third layer.

In one example the common ground plane is formed from a sheet of conductive material such as a metal.

In one example each of the first layer, second layer and third layer include a conductive sublayer and a dielectric sublayer, and the common ground plane is formed from a portion of the conductive sublayer of the second layer.

In one example the dielectric opening overlaps at least a portion of the first inductor when viewed from a direction perpendicular to the plurality of layers.

In one example the dielectric opening overlaps at least a portion of the second inductor when viewed from a direction perpendicular to the plurality of layers.

In one example the multi-chip module further comprises an additional common ground plane spanning over at least a portion of the third layer.

In one example the multi-chip module further comprises an additional dielectric opening through the additional common ground plane, said additional dielectric opening located between the first inductor and the second inductor.

In one example the additional dielectric opening is positioned adjacent to the second inductor in the third layer.

In one example the additional dielectric opening overlaps at least a portion of the first inductor when viewed from a direction perpendicular to the plurality of layers.

In one example the multi-chip module further comprises a fourth layer, with the third layer positioned between the second layer and the fourth layer, and the second inductor is included in both the third layer and the fourth layer.

In one example the second inductor is formed from signal traces on both the third layer and the fourth layer.

In one example the low noise amplifier circuit is a single-stage or multi-stage amplifier including a common-source or common-emitter amplifier stage.

In one example the dielectric opening is configured to increase mutual inductance between the first inductor and second inductor.

According to another embodiment there is provided a packaged module. The packaged module comprises: a packaging substrate; and a multi-chip module mounted on the packaging substrate, the multi-chip module including a plurality of layers including a first layer, a second layer and a third layer, said second layer positioned between the first layer and third layer; a low noise amplifier circuit distributed across the plurality of layers and including a first inductor in the first layer, a second inductor in the third layer, and a transistor; a common ground plane spanning over at least a portion of the second layer; and a dielectric opening through the common ground plane, said dielectric opening located between the first inductor and the second inductor.

According to another embodiment there is provided a wireless device. The wireless device comprises: an antenna configured to receive a radio frequency signal; a front end module in communication with the antenna, the front end module including a multi-chip module including a plurality of layers including a first layer, a second layer and a third layer, said second layer positioned between the first layer and third layer; a low noise amplifier circuit distributed across the plurality of layers and including a first inductor in the first layer, a second inductor in the third layer, and a transistor; a common ground plane spanning over at least a portion of the second layer; and a dielectric opening through the common ground plane, said dielectric opening located between the first inductor and the second inductor; and a transceiver in communication with the front end module.

According to one embodiment there is provided a multi-chip module. The multi-chip module comprises: a plurality of layers including a first layer, a second layer and a third layer, said second layer positioned between the first layer and third layer; a low noise amplifier circuit distributed across one or more of the plurality of layers; a first inductor of the low noise amplifier circuit included in the first layer; and a second inductor of the low noise amplifier circuit included in the first layer and positioned adjacent to the first inductor, with a winding axis of the first inductor either parallel or perpendicular to a winding axis of the second inductor.

In one example the first inductor is connected to a gate terminal or base terminal of a transistor in the low noise amplifier circuit.

In one example the second inductor is connected to a source terminal or emitter terminal of the transistor in the low noise amplifier circuit.

In one example the transistor is included in the first layer.

In one example the transistor is implemented within an integrated circuit in the multi-chip module.

In one example the first inductor is a surface-mount device.

In one example the second inductor is a surface-mount device.

In one example the winding axis of the second inductor is parallel to the first layer.

In one example the winding axis of the first inductor is perpendicular to the first layer.

In one example the first inductor is configured such that a current received at an input of the low noise amplifier circuit travels in a clockwise direction through the first inductor when viewed along the winding axis from a direction above the first layer.

In one example the first inductor is configured such that a current received at an input of the low noise amplifier circuit travels in an anticlockwise direction through the first inductor when viewed along the winding axis from a direction above the first layer.

In one example the winding axis of the first inductor is parallel to the first layer.

In one example the winding direction of the first inductor is the same as the winding direction of the second inductor.

In one example each of the first layer, second layer and third layer include a conductive sublayer and a dielectric sublayer.

In one example the low noise amplifier circuit is a single-stage or multi-stage amplifier including a common-source or common-emitter amplifier stage.

According to another embodiment there is provided a packaged module. The packaged module comprises: a packaging substrate; and a multi-chip module mounted on the packaging substrate, the multi-chip module including a plurality of layers including a first layer, a second layer and a third layer, said second layer positioned between the first layer and third layer; a low noise amplifier circuit distributed across one or more of the plurality of layers; a first inductor of the low noise amplifier circuit included in the first layer; and a second inductor of the low noise amplifier circuit included in the first layer and positioned adjacent to the first inductor, with a winding axis of the second inductor either parallel or perpendicular to a winding axis of the first inductor.

In one example the winding axis of the second inductor is parallel to the first layer.

In one example the winding axis of the first inductor is perpendicular to the first layer.

In one example the winding axis of the first inductor is parallel to the first layer.

According to another embodiment there is provided a wireless device. The wireless device comprises: an antenna configured to receive a radio frequency signal; a front end module in communication with the antenna, the front end module including a multi-chip module including a plurality of layers including a first layer, a second layer and a third layer, said second layer positioned between the first layer and third layer; a low noise amplifier circuit distributed across one or more of the plurality of layers; a first inductor of the low noise amplifier circuit included in the first layer; and a second inductor of the low noise amplifier circuit included in the first layer and positioned adjacent to the first inductor, with a winding axis of the second inductor either parallel or perpendicular to a winding axis of the first inductor; and a transceiver in communication with the front end module.

Still other aspects, embodiments, and advantages of these exemplary aspects and embodiments are discussed in detail below. Embodiments disclosed herein may be combined with other embodiments in any manner consistent with at least one of the principles disclosed herein, and references to “an embodiment,” “some embodiments,” “an alternate embodiment,” “various embodiments,” “one embodiment” or the like are not necessarily mutually exclusive and are intended to indicate that a particular feature, structure, or characteristic described may be included in at least one embodiment. The appearances of such terms herein are not necessarily all referring to the same embodiment.

### BRIEF DESCRIPTION OF THE DRAWINGS

Various aspects of at least one embodiment are discussed below with reference to the accompanying figures, which are not intended to be drawn to scale. The figures are included to provide illustration and a further understanding of the various aspects and embodiments, and are incorporated in and constitute a part of this specification, but are not intended as a definition of the limits of the invention. In the figures, each identical or nearly identical component that is illustrated in various figures is represented by a like numeral. For purposes of clarity, not every component may be labeled in every figure. In the figures:

FIG. 1 is a multi-chip module according to aspects of the present invention;

FIG. 2 is a circuit diagram for an LNA circuit according to aspects of the present invention;

FIG. 3 is a multi-chip module according to aspects of the present invention;

FIG. 4A shows a first layer of the multi-chip module of FIG. 3;

FIG. 4B shows a second layer of the multi-chip module of FIG. 3;

FIG. 4C shows a third layer of the multi-chip module of FIG. 3;

FIG. 4D shows a fourth layer of the multi-chip module of FIG. 3;

FIG. 5 is a smith chart showing input impedance characteristics of an LNA circuit in the multi-chip module of FIGS. 3 and 4A to 4D;

FIG. 6 is a multi-chip module according to aspects of the present invention;

FIG. 7A shows a perspective view of a multi-chip module according to aspects of the present invention;

FIG. 7B shows a perspective view of a multi-chip module according to aspects of the present invention;

FIG. 7C shows a perspective view of a multi-chip module according to aspects of the present invention;

FIG. 8 is a smith chart showing input impedance characteristics of LNA circuits in the multi-chip modules of FIGS. 7A to 7C;

FIG. 9 is a packaged module according to aspects of the present invention; and

FIG. 10 is a mobile device according to aspects of the present invention.

### DETAILED DESCRIPTION

Aspects and embodiments described herein are directed to a multi-chip module including a low noise amplifier circuit. The layout of the multi-chip module, and in particular the use of a dielectric opening or specific positioning of inductors to alter a mutual inductance in the low noise amplifier circuit, results in an improved input impedance of the low noise amplifier circuit for better input matching.

It is to be appreciated that embodiments of the methods and apparatuses discussed herein are not limited in application to the details of construction and the arrangement of components set forth in the following description or illustrated in the accompanying drawings. The methods and apparatuses are capable of implementation in other embodiments and of being practiced or of being carried out in various ways. Examples of specific implementations are provided herein for illustrative purposes only and are not intended to be limiting. Also, the phraseology and terminology used herein is for the purpose of description and should not be regarded as limiting. The use herein of “including,” “comprising,” “having,” “containing,” “involving,” and variations thereof is meant to encompass the items listed thereafter and equivalents thereof as well as additional items. References to “or” may be construed as inclusive so that any terms described using “or” may indicate any of a single, more than one, and all of the described terms.

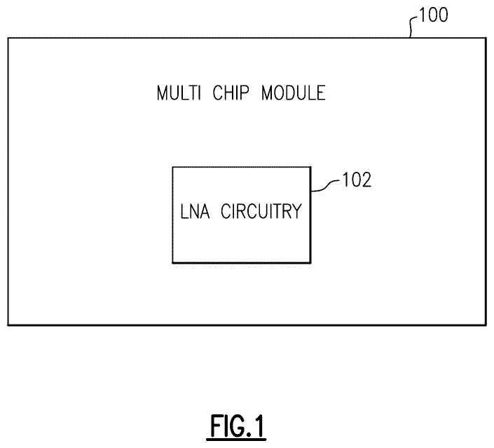

FIG. 1 shows a multi-chip module (MCM) 100 that includes a low noise amplifier (LNA) circuit 102. The multi-chip module device 100 may be a radio-frequency (RF) chip or the like. The multi-chip module 100 includes a plurality of layers formed from materials including dielectric materials or conductive materials such as metals, e.g. copper or aluminum. The LNA circuit 102 is formed from components within the multi-chip module 100 such as one or more switches, for example transistors including bipolar junction transistors (BJTs) and/or field-effect transistor (FETs), as well other electronic components such as inductors, capacitors and/or resistors. The LNA circuit 102 may be distributed across the layers of multi-chip module 100, meaning that the various components of the LNA circuit may be located on and/or formed within different layers of the multi-chip module 100.

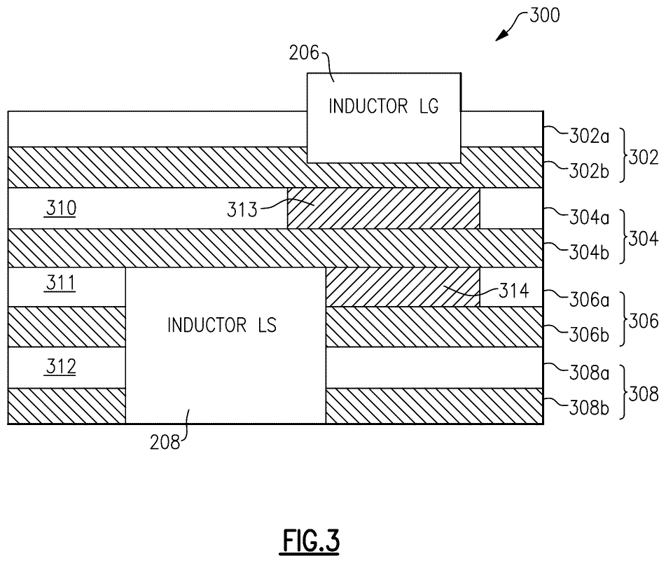

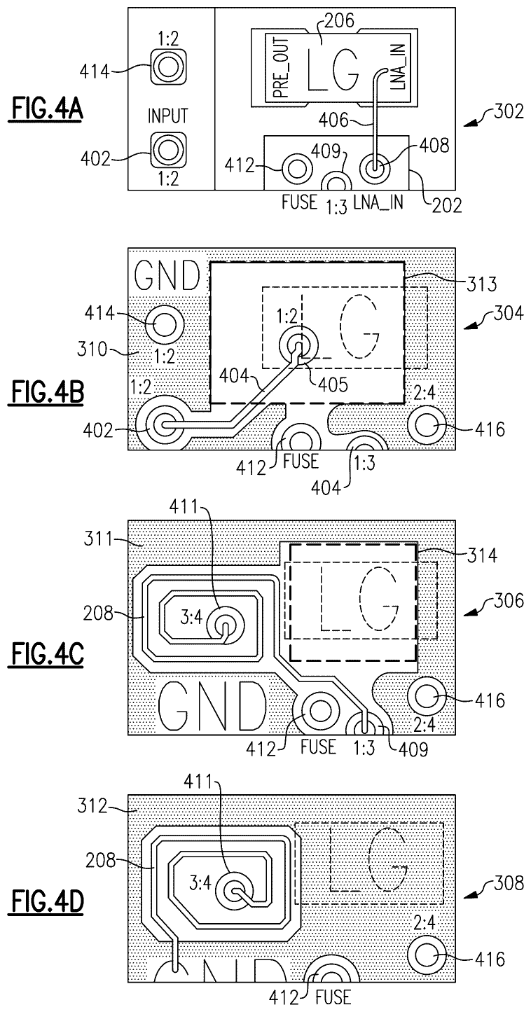

In general, the multi-chip module 100 includes a plurality of integrated circuits (ICs) and/or other discrete electronic components packaged together. For example, as discussed in relation to FIGS. 3 to 4D below, multi-chip modules in embodiments of the present disclosure may include components such as SMD inductors or ICs including LNA transistors. Further, in some embodiments other ICs and components could be included on the multi-chip module 100 including but not limited to passive filters such as bulk acoustic wave (BAW) or surface acoustic wave (SAW) filters, complementary metal-oxide-semiconductor (CMOS) controllers, and/or silicon on insulator (SOI) or silicon-germanium LNAs. In embodiments, integrated circuits included in the multi-chip module 100 may be flip chip devices or other types of packaged chip modules.

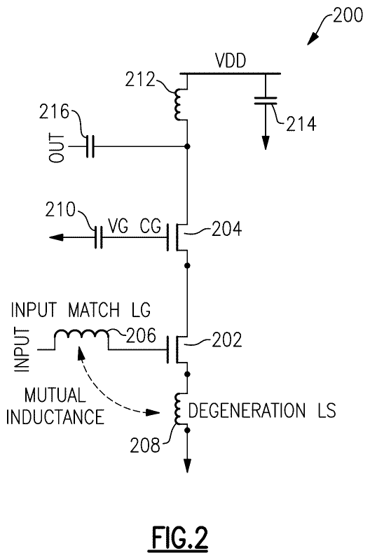

FIG. 2 shows a circuit diagram for an LNA circuit 200 according to one embodiment. The LNA circuit 200 includes a two-stage cascode amplifier having a first FET 202 in a common source amplifier stage and a second FET 204 in a common gate amplifier stage. The gate terminal of the first FET 202 receives, via a first inductor (LG) 206, an input signal to be amplified. The source terminal of the first FET 202 is connected to ground via a second inductor (LS) 208, which acts as a degeneration inductor. The drain terminal of the first FET 202 is connected to the source terminal of the second FET 204. The gate terminal of the second FET 204 is connected to ground via a first capacitor 210. The drain terminal of the second FET 204 is connected to a supply voltage VDD via a third inductor 212, with a second capacitor 214 connected between the supply voltage VDD and ground. The LNA circuit 200 outputs an amplified signal via a third capacitor 216 at the drain terminal of the second FET 204.

The LNA circuit 200 of FIG. 2 may be implemented within the multi-chip module 100 of FIG. 1. Both of the first and second inductors 206,208 in particular are included in the MCM 100, to provide an improved noise figure (NF) performance.

In use, the first inductor 206 receives the signal to be amplified from an antenna or LNA pre-filter, or the like, which will have a fixed constant impedance, typically set at 50 ohm as standard. The techniques discussed herein increase the mutual inductance between the first inductor (LG) 206 and second inductor (LS) 208, in order to increase the real part of the input impedance (Zin) of the LNA (so that the real part of Zin is closer to the impedance of the antenna or LNA pre-filter, e.g. 50 ohm), in order to improve the input matching of the LNA.

In some embodiments, various other types of LNA circuits may be used. For example single-stage amplifier circuits may be used, such a common-source LNA. Alternatively multi-stage amplifiers with more than two stages may also be used. Further, as well as amplifiers including FETs, other types of switches or transistors could be used in the LNA circuit, such as a BJT in a common-emitter amplifier stage. In the case that BJTs are used in the LNA circuit 200 of FIG. 2, the base terminal of the BJT would be connected in place of the gate terminal of the first or second FET, the emitter terminal of the BJT would be connected in place of the source terminal of the first or second FET, and the collector terminal of the BJT would be connected in place of the drain terminal of the first or second FET.

Adjusting Mutual Inductance with Dielectric Openings

FIG. 3 shows a multi-chip module (MCM) 300 according to one embodiment of the disclosure. In the embodiment of FIG. 3, a dielectric opening is included in the multi-chip module 300 between inductors equivalent to the first and second inductors 206,208 discussed in relation to FIG. 2, to increase the mutual inductance and thus improve input matching for the LNA circuit. It is noted that the view shown in FIG. 3 shows only a portion of an MCM, and may form part of a larger MCM which may include further circuitry or functionalities.

In more detail, the multi-chip module 300 includes a first layer 302, a second layer 304, a third layer 306, and a fourth layer 308. The layers are stacked with the second layer 304 beneath the first layer 302 when viewed in the orientation shown in FIG. 3 (i.e. with the first layer considered to be the top layer), the third layer 306 beneath the second layer 304, and the fourth layer 308 beneath the third layer 306. The second layer 304 is therefore positioned between the first layer 302 and the third layer 306, and the third layer 306 is positioned between the second layer 304 and the fourth layer 308. In general, the fourth layer may be omitted in some embodiments. Further, in some embodiments the multi-chip module may include more than four layers.

Each of the layers 302,304,306,308 includes a conductive sublayer and a dielectric sublayer. Specifically, the first layer 302 includes a conductive sublayer 302a and a dielectric sublayer 302b, the second layer 304 includes a conductive sublayer 304a and a dielectric sublayer 304b, the third layer 306 includes a conductive sublayer 306a and a dielectric sublayer 306b, and the fourth layer 308 includes a conductive sublayer 308a and a dielectric sublayer 308b. Each conductive sublayer is formed from a conductive material such as a metal, e.g. copper or aluminum, with sections of the conductive sublayer removed and replaced with dielectric material as necessary to form electrical components and connections, such as signal traces or the like. Each dielectric sublayer is formed from a dielectric material providing electrical insultation between two adjacent conductive sublayers. As shown in FIG. 3, the conductive sublayer is positioned over the top of each dielectric sublayer, such that the sublayers alternate between conductive and dielectric as you move through the layers of the MCM. The dielectric sublayers are shown shaded in FIG. 3, to distinguish them from the unshaded conductive sublayers.

The multi-chip module 300 has implemented therein an LNA circuit, such as the LNA circuit 200 of FIG. 2. The components of the LNA circuit can be distributed at various locations and within various layers of the MCM 300. In the present embodiment the first inductor (LG) 206 is located in the first (top) layer 302 of the MCM 300, and the second inductor (LS) 208 is located in the third and fourth layers 306,308 of the MCM 300. Although the second inductor 208 is distributed across both the third and fourth layers 306,308 in the present embodiment, the second inductor 208 may be located solely on the third layer 306 in some cases. Further, in some embodiments the position of the inductors could be interchanged, with the LS inductor located on the first layer 302 as the first inductor and the LG inductor located on the third layer 206 or third and fourth layers 306,308 as the second inductor. The remaining components of the LNA circuit, other than the first and second inductors 206,208, such as the first FET 202, have not been shown in FIG. 3 for simplicity. However, in some embodiments the MCM may include an IC to implement the first FET 202, which may be located on the first layer in some embodiments. The components of the LNA circuit are connected together by various signal traces and vias within the MCM 300, again not shown in FIG. 3.

The first layer 302 contains electrical components including the first inductor 206 included thereon or therein. For example, in the present embodiment the first inductor 206 is a surface mount device (SMD) situated on the first layer 302. However in alternative embodiments, the first inductor 206 may be formed as a signal trace within the first layer 302. Such a signal trace may be formed within the conductive sublayer 302a of the first layer 302, for example by etching the signal trace into the conductive sublayer 302a of the first layer 302. The conductive sublayer 302a of the first layer 302 is separated from the second layer 304 by the dielectric sublayer 302b of the first layer 302.

In the present embodiment, and as discussed and shown in more detail in relation to FIGS. 4C and 4D below, the second inductor 208 is formed from signal traces on both the third layer 306 and the fourth layer 308 which are connected together. However, in general any technology for forming an inductor within a layer of a multi-chip module may be used. It is noted that the inductors shown in FIG. 3 are not to scale, and although the inductors are shown as extending over dielectric sublayers in FIG. 3, the inductors may be formed in the conductive sublayers only, e.g. by signal traces in the conductive sublayers.

The second layer 304 is partially spanned by a common grounding plane 310. The grounding plane 310 is formed in the conductive sublayer 304a of the second layer 304, and may be formed by etching of the conductive sublayer 304a of the second layer 304, or the like. The ground plane 310 is thus a sheet of conductive material, such as a metal (e.g. copper or aluminum), which is connected to a common constant reference voltage such as ground or 0V. In the present embodiment, the third layer 306 and fourth layer 308 are also partially spanned by similar (additional) grounding planes 311,312, which span the areas around the components present in the third and fourth layers 306,308, such as the second inductor 208.

As shown in FIG. 3, a dielectric opening 313 is included in the second layer 304, in particular in the conductive sublayer 304a of the second layer 304. The dielectric opening 313 is formed as a window or opening through the metal sheet of the common grounding plane 310, which is filled with any suitable dielectric material. The dielectric opening 313 is positioned between the first inductor 206 and the second inductor 208, so as to provide a path between the inductors 206,208 which passes through dielectric material only. Put another way, the dielectric opening 313 overlaps at least a portion of the first and second inductors 206,208 when viewed in a direction perpendicular/normal to the plane of the layers 302 to 308 of the MCM 300. In the view of the FIG. 3, the dielectric opening 313 is therefore underneath at least part of the first inductor 206, and is above at least part of the second inductor 208.

In some embodiments, the dielectric opening 313 may be formed in the conductive sublayer 304a of the second layer 304 during manufacture by removing metallic material by etching, and then filling the etched region with dielectric material. However other techniques of manufacturing the dielectric opening 313 are also possible.

The dielectric opening 313 provides a path between the first and second inductors 206,208 that contains only dielectric material, and thus provides a pathway for magnetic flux to route between the first and second inductors 206,208. This results in an increase in the mutual inductance of the first and second inductors 206,208 compared to, for example, an MCM where a grounding plane located in a layer between the first and second inductors extends the entire way underneath the first inductor 206 and above the second inductor 208, without any cut out sections or openings provided in the grounding plane 310. Such a grounding plane would separate the first and second inductors 206,208 entirely, preventing magnetic flux from either of the first or second inductors 206,208 influencing the other inductor. The increase in mutual inductance due to the dielectric opening 313 increases the real part of the input impedance (Zin) of the LNA circuit, as discussed above, thus improving input matching of the LNA.

By modifying the size of the dielectric opening 313 (i.e. the area of the portion cut out of the grounding plane 310) and modifying the relative position of the dielectric opening 313 to the first and second inductors 206,208, the mutual inductance between the first and second inductors 206,208 adjusted to tune the real part of the input impedance. For example, the size and position of the dielectric opening 313 can be chosen to set the real part of the input impedance to as close to 50 ohm as possible. In general, an increase in the size of the dielectric opening 313 will result in an increase in mutual inductance and thus increase in the real part of the input impedance. Further, a larger overlap (when viewed perpendicular to the layers) between the dielectric opening 313 and each of the first or second inductors 206,208 will result in an increased mutual inductance.

In the embodiment shown in FIG. 3, an additional dielectric opening 314 is included in the additional common grounding plane 311 in the third layer 306. Analogous to the dielectric opening 313 in the second layer 304, the additional dielectric opening 314 is formed as an opening cut out of the sheet of the additional common ground plane 311, and then filled with dielectric material. Analogously to the dielectric opening 313, the additional dielectric opening 314 may be formed in the conductive sublayer 306a of the third layer 306 during manufacture by removing metallic material by etching, and then filling the etched region with dielectric material.

The additional dielectric opening 314 is located between the first inductor 206 and the second inductor 208, thus providing additional dielectric material through which magnetic flux can travel between the first and second inductors 206,208. In particular, the additional dielectric opening 314 is positioned beneath the first inductor 206, i.e. overlapping at least part of the first inductor 206 when viewed from a direction perpendicular to the layers. Further, the additional dielectric opening 314 is positioned directly adjacent to the second inductor 208 in the third layer 306 (in particular the conductive sublayer 306a of the third layer 306), as best shown in FIG. 4C below.

The additional dielectric opening 314 can further increase the mutual inductance between the first and second inductors 206,208, and thus further increase the real part of the input impedance (Zin) to improve impedance matching. However, such additional dielectric openings 314 are optional, and may be absent in some embodiments.

In further embodiments, an additional dielectric opening may also be present in the fourth layer 308 as well as in the third layer 306. Such an additional dielectric opening in the fourth layer would be similar to the additional dielectric opening 314 in the third layer of FIG. 3, and thus a repeat description will be omitted. Although not present in the embodiment shown in FIG. 3, including an additional dielectric opening in the fourth layer can further increase the mutual inductance between the first and second inductors 206,208.

Although not shown in FIG. 3, the MCM 300 may include a solder mask layer on top of the first layer 302 in some embodiments. Additionally, the conductive sublayer 302a of the first layer 302 may be largely or entirely removed in some embodiments.

FIGS. 4A to 4D show a plan view of a portion of each layer of the multi-chip module 300 of FIG. 3 in more detail. FIG. 4A shows the first layer 302, and in particular a view looking down onto the top of the MCM 300 in FIG. 3. FIG. 4B shows the second layer 304, and in particular a view looking down onto the conductive sublayer 304a in FIG. 3. FIG. 4C shows the third layer 306, and in particular a view looking down onto the conductive sublayer 306a in FIG. 3. FIG. 4D shows the fourth layer 308, and in particular a view looking down onto the conductive sublayer 308a in FIG. 3. It is noted that the views in FIG. 4A to 4D show only a portion of a MCM, and may form part of a larger MCM which may include further circuitry or functionalities.

As shown in FIG. 4A, the first inductor 206 is an SMD mounted on the first layer 302. The first layer 302 also includes an first via 402, which corresponds to the INPUT node in the LNA circuit of FIG. 2. The first via 402 receives an input from an antenna or LNA pre-filter located elsewhere in the MCM 300 (not shown), or from separate circuitry.

The first via 402 extends between the first and second layers (indicated by the 1:2 next to first via 402 in FIGS. 4A and 4B), in order to transfer the signal input at the first via 402 on the first layer 302 to the second layer 304. Put another way, the first via 402 extends between the conductive sublayer 302a of the first layer 302 and the conductive sublayer 304a of the second layer 304. In the second layer 304, as shown in FIG. 4B, the first via 402 is coupled to a second via 405 by a first signal trace 404. The first signal trace 404 corresponds to the wire in the circuit of FIG. 2 between the INPUT node and first inductor 206. The second via 405 connects the first signal trace 404 on the second layer 304 to the first inductor 206 on the first layer 302. The first signal trace 404 may be etched into the conductive sublayer 304a of the second layer 304.

The first inductor 206 is further connected to the first FET 202 on the first layer 302 by a second signal trace 406 on the first layer. Only a portion of the first FET 202 is shown schematically in the view of FIG. 4A. The first FET 202 may be implemented in an IC in some embodiments. The second signal trace 406 is connected to terminal 408 (LNA_IN) of the first FET 202, which corresponds to the gate terminal of the first FET 202. Thus the second signal trace 406 corresponds to the wire in the circuit of FIG. 2 between the first inductor 206 and the gate of the first FET 202. The second signal trace 406 may be etched into the conductive sublayer 302a of the first layer 302.

Although the first inductor 206 is located on the first layer 302, in each of FIGS. 4B to 4D the first inductor 206 is shown superimposed onto the second, third and fourth layers 304,306,308 in broken lines. This is merely to aid understanding, and illustrate the position of the components on the first layer relative to the other layers, rather than to indicate that the first inductor 206 is present on the second, third or fourth layers.

As can be seen in FIG. 4B, the grounding plane 310 is present in the second layer 304 (specifically the conductive sublayer 304a of the second layer 304). The grounding plane acts to prevent interactions between components in the first and third layers 302,306. The dielectric opening 313 discussed in relation to FIG. 3 can be seen in FIG. 4B passing through the grounding plane 310. In FIG. 4B the grounding plane 310 is shown with a shading pattern to help distinguish it from dielectric material in the dielectric opening 313 which is not shaded. The dielectric opening 313 is positioned beneath a portion of the first FET 206 such that magnetic flux can pass through the grounding plane 310 in the second layer 304 to increase the mutual inductance with the second inductor 208 on the third layer 306.

The first, second, and third layers 302,304,306 shown in FIGS. 4A to 4C further include a third via 409 (partially shown), which is coupled to the source terminal of the first FET 202 in the first layer 302. The third via 409 is connected to a signal trace on third layer 306, said signal trace forming a first portion of the second inductor 208. The signal trace on the third layer 306 forming a portion of the second 208 inductor could be formed by etching the signal trace into the conductive sublayer 306a of the third layer 306. As can be seen in FIG. 4C, the first portion of the second inductor 208 is formed from a substantially spiral signal trace surrounded by the (additional) common grounding plane 311. The signal trace of the second inductor 208 is separated from the common grounding plane 311 by dielectric material. In FIG. 4C the common grounding plane 311 is shown with a shading pattern, whereas the dielectric material and signal trace is unshaded.

Similar to the grounding plane 310 on the second layer 304, the additional grounding plane 311 in the conductive sublayer 306a of the third layer 306 acts to prevent interactions between components in the second and fourth layers 304,308. The additional dielectric opening 314 discussed in relation to FIG. 3 can be seen in FIG. 4C passing through the additional grounding plane 311. The additional dielectric opening 314 is positioned beneath a portion of the first FET 206 and adjacent to the second inductor 208, such that magnetic flux can pass through the grounding plane 311 in the third layer 306 to increase the mutual inductance with the second inductor 208. As seen in FIG. 4C, the size (area) of the additional dielectric opening 314 is less than the size (area) of the dielectric opening 313 in the present embodiment. In general the relative sizes of the dielectric opening 313 and additional dielectric opening 314 may be chosen to tune the real part of the input impedance, as well as based on available spatial requirements within the MCM.

Returning to the second inductor 208, the first portion of the second inductor 208 on the third layer 306 has a first end and a second end. The first end is connected to the third via 409 as mentioned previously. The second end is connected to a fourth via 411, which connects to a second portion of the second inductor 208 on the fourth layer 308. Analogously to the third layer 306, the second portion of the second inductor 208 is formed from a substantially spiral signal trace surrounded by the (additional) common grounding plane 312 on the fourth layer 308. The signal trace of the second inductor 208 is separated from the common grounding plane 312 by dielectric material, with the common grounding plane 312 shown with a shading pattern in FIG. 4D, whereas the dielectric material and signal trace are unshaded.

The second portion of the second inductor 208 on the fourth layer 306 has a first end and a second end. The first end is connected to the fourth via 411 as mentioned previously. The second end is connected to the common grounding plane 312 to ground the second inductor 208 (as shown in FIG. 2).

The multi-chip module 300 may also include, shown in FIGS. 4A to 4D, a fifth via 412 on each of the first, second, third, and fourth layers corresponding to a FUSE element. Further, multi-chip module 300 may also include a sixth via 414 on the first and second layers, connecting to the common grounding plane 310, and a seventh via 416 on the second, third and fourth layers 304,306,308, connecting the common grounding plane 310 to the additional common grounding planes 311,312.

As mentioned, FIGS. 4A to 4D only show a partial view of the layers of a multi-chip module, and the complete MCM may include further circuitry and components which are not shown. For example, the views of FIGS. 4A to 4D do not show the drain terminal of first FET 202, or the remaining circuitry connected to drain terminal of the first FET 202 in FIG. 2, such as the second FET 204, the first capacitor 210, the third inductor 212, the second capacitor 214, or the third capacitor 216. These components may be present on various locations, and within various layers of the MCM in general. Further, the MCM may include other entirely separate circuitry and/or ICs in some embodiments.

In general, although the LNA transistor (namely the first FET 202) is located in the first layer in the above described embodiments, the transistor could be located in other layers in alternative embodiments. Further, in the present embodiments the first inductor 206 is an SMD and the first layer 302 is the top layer of the MCM 300. However, in other embodiments, for example when the first inductor 206 is formed from a signal trace, the first inductor 206 could be located on a lower layer in the MCM, with the dielectric opening 313 positioned underneath the first inductor in the layer below. Put another way, when first inductor 206 is formed from a signal trace in the conductive sublayer 302a of the first layer 302, the first layer 302 does not necessarily need to be the top layer of the MCM, but there could instead be layers above the first layer 302.

As discussed above, the second indicator 208 may be formed on the third layer 306 alone, or could be formed on the third and fourth layers. Further, in some embodiments the second inductor 208 could be formed on layers in addition to the third and fourth layers 306,308, such as additional layers below the fourth layer 308.

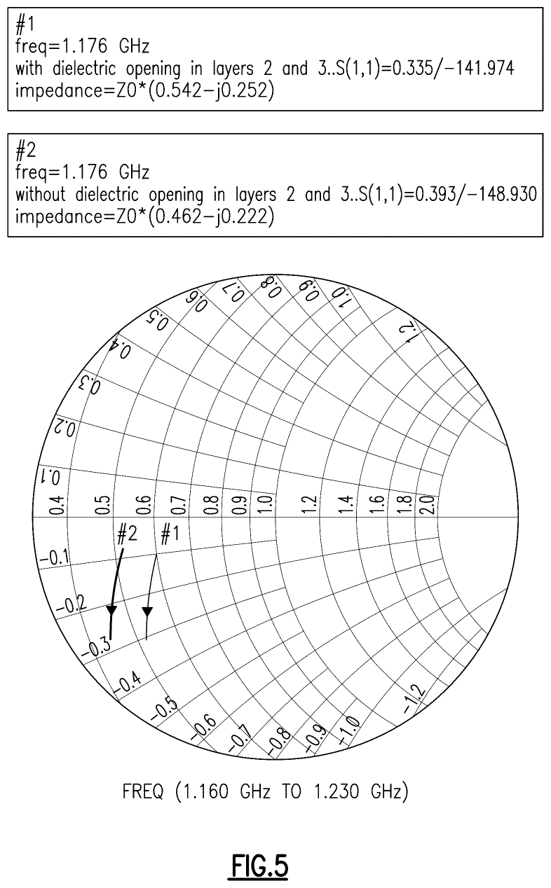

FIG. 5 is a smith chart showing the S11 characteristics and input impedance of an LNA implemented according to the embodiment of FIGS. 3 to 4D. In particular, the curve labeled #1 in FIG. 5 shows the input impedance for the multi-chip module 300 of FIGS. 3 and 4A to 4D, having the dielectric opening 313 and additional dielectric opening 314 present in the second and third layers 304,306 respectively. The curve labeled #2 in FIG. 5 shows the input impedance for a comparative example, identical to the multi-chip module 300 of FIGS. 3 and 4A to 4D, but without the dielectric opening 313 and additional dielectric opening 314 in the common grounding planes (such that the common grounding plane 310 extends underneath the first inductor 206). As can be seen in FIG. 5, the real part of the input impedance is increased from 0.462*Z0 to 0.542*Z0 when the dielectric opening 313 and additional dielectric opening 314 are present, where Z0=50 ohm. The real part of Zin is thus improved from 23.1 ohm to 27.1 ohm in the example of FIG. 5.

The multi-chip module 300 may be manufactured using various techniques known in the art. For example, in some embodiments the multi-chip module 300 can be built up one layer at a time from dielectric and metal sublayers. Techniques including but not limited to deposition and etching may be used to implement the various electronic components within the metal conductive sublayers of the MCM, including the dielectric opening 313 and additional dielectric opening 314.

Adjusting Mutual Inductance with Inductor Positioning

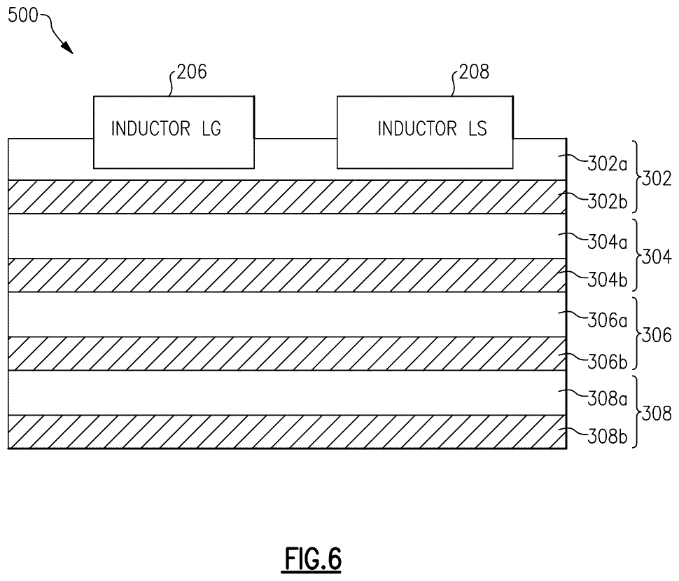

FIG. 6 shows a multi-chip module (MCM) 500 according to another embodiment of the disclosure. Analogously to the MCM 300 of FIG. 3, the MCM 500 of FIG. 6 includes a first layer 302, second layer 304, third layer 306, and fourth layer 308, each including a conductive sublayer 302a,304a,306a,308a, and a dielectric sublayer 302b,304b,306b,308b. The MCM 500 may include more or less than four layers in other embodiments. The multi-chip module 500 has implemented therein an LNA circuit, such as the LNA circuit 200 of FIG. 2, or an alternative single-stage or multi-stage LNA circuit including a common-source amplifier stage. Analogously to the MCM 300 of FIG. 3, the components of the LNA circuit in the MCM 500 can be distributed at various locations and within various layers of the MCM 500.

Similarly to the MCM 300 of FIG. 3, in the MCM 500 of FIG. 6 the first inductor (LG) 206 and second inductor (LS) 208 are shown, but the remaining components of the LNA circuit other than the first and second inductors 206,208, such as the first FET 202, have not been shown in FIG. 6 for simplicity. However, in some embodiments the MCM 500 may include an IC to implement the first FET 202, which may be located on the first layer in some embodiments. The components of the LNA circuit are connected together by various signal traces and vias within the MCM 500, again not shown in FIG. 6.

In general, the description of the MCM 300 of FIG. 3 above applies analogously to the MCM 500 of FIG. 6. However, the MCM 500 of FIG. 6 differs from the MCM 300 of FIG. 3 in that, rather than including dielectric openings within the layers of the MCM to modify the mutual inductance between the first and second inductors, in the MCM 500 specific positioning of the LS and LG inductors of the LNA circuit 200 is used to modify the mutual inductance in order to improve input impedance matching.

In particular, as shown in FIG. 6, in the MCM 500 the first inductor (LG) 206 and second inductor (LS) 208 of the LNA circuit 200 are both included in the first layer 302. In the present embodiment both the first and second inductors are surface mount devices (SMDs), however in general other forms of inductors may be used, such as inductors formed from signal traces in the conductive sublayer 302a of the first layer 302. The first inductor 206 and second inductor 208 are positioned adjacent to each other on the first layer, to increase the mutual inductance between the first and second inductors 206,208 in order to set the real part of the input impedance as close to 50 ohms as possible, and thus improve the input matching of the LNA circuit. In general, the distance between the first and second inductors 206,208 on the first layer 302 can be adjusted to tune the real part of the input impedance.

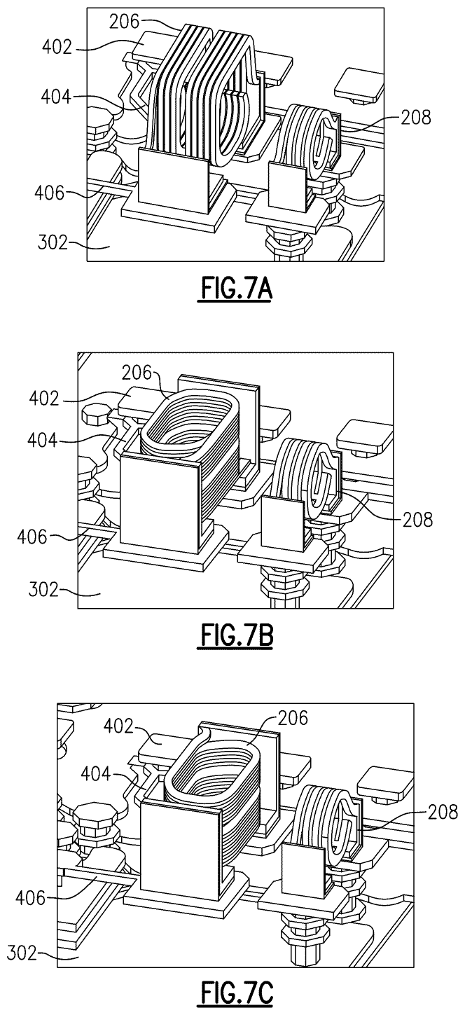

Further, the first inductor 206 and second inductor 208 each have a winding axis (not shown in FIG. 6) about which the wire turns in each inductor are wound. As discussed in more detail in relation to FIGS. 7A to 7C, in the MCM 500 of the present embodiment the winding axes of the first and second inductors 206,208 are either parallel or perpendicular to each other. By modifying the relative orientation of the winding axes of the inductors, the polarity (i.e. magnetic flux direction) is changed. Such a change in polarity further alters the mutual inductance between the first and second inductor 206,208 (in addition to any change in the separation distance between the inductors 206,208), and thus the real part of the input impedance of the LNA circuit can be improved by modifying the relative orientation of the winding axes of the inductors.

FIGS. 7A to 7C show perspective views of the MCM 500 of FIG. 6 for different configurations of the first and second inductors 206,208. Specifically, the views of FIGS. 7A to 7C are looking down from above the MCM 500 as shown in FIG. 6, i.e. from above the first layer. In each of FIGS. 7A to 7C the first inductor 206 and second inductor 208 can be seen on the first layer. Further, dielectric material (such as the dielectric sublayers) is omitted in each of FIGS. 7A to 7C, to allow the components within the layers to be seen. Specifically, in each of FIGS. 7A to 7C components equivalent to the first (INPUT) via 402, the first signal trace 404 and the second signal trace 406 described above in relation to FIGS. 4A to 4D can be seen.

FIG. 7A shows a first configuration for the first and second inductors 206,208 on the first layer 302 of the MCM 500. In the configuration of FIG. 7A the winding axes of the first and second inductors 208 are parallel to each other. In particular, the winding axes of both the first inductor (LG) 206 and the second inductor (LS) 208 are parallel to the first layer 302. Further, the winding direction of the first inductor 206 is the same as the winding direction of the second inductor 208 in the embodiment of FIG. 7A.

FIG. 7B shows a second configuration for the first and second inductors 206,208 on the first layer 302 of the MCM 500. In the configuration of FIG. 7B the winding axes of the first and second inductors 208 are perpendicular to each other. In particular, the winding axis of first inductor (LG) 206 is perpendicular to the first layer 302 and the winding axis of the second inductor (LS) 208 is parallel to the first layer 302. Further, in the embodiment of FIG. 7B the first inductor 206 has a winding direction and electrical connection to the LNA circuit such that a current received at the input of the LNA circuit 200 (i.e. at the first via 402) travels in a clockwise direction through the first inductor 206 when viewed along the winding axis from a direction above the first layer (i.e. when viewed from the top in the orientation of FIG. 6).

FIG. 7C shows a third configuration for the first and second inductors 206,208 on the first layer 302 of the MCM 500. In the configuration of FIG. 7C the winding axes of the first and second inductors 208 are perpendicular to each other. In particular, the winding axis of first inductor (LG) 206 is perpendicular to the first layer 302 and the winding axis of the second inductor (LS) 208 is parallel to the first layer 302. Further, in the embodiment of FIG. 7C the first inductor 206 has a winding direction and electrical connection to the LNA circuit such that a current received at the input of the LNA circuit 200 (i.e. at the first via 402) travels in an anticlockwise direction through the first inductor 206 when viewed along the winding axis from a direction above the first layer (i.e. when viewed from the top in the orientation of FIG. 6).

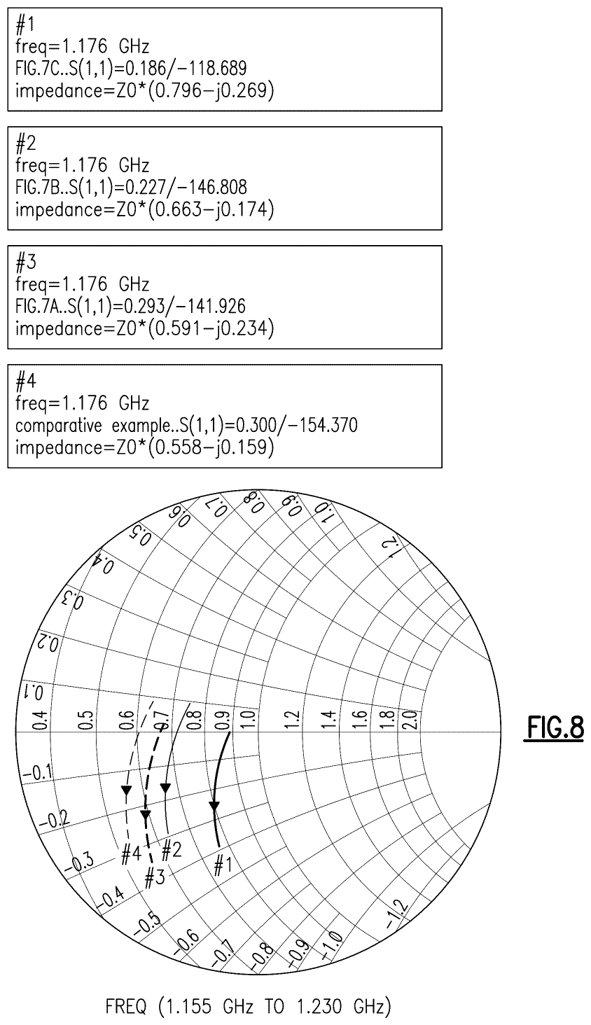

FIG. 8 is a smith chart showing the S11 characteristics and input impedance of a LNA implemented according to the embodiments of FIGS. 6 to 7C. In particular, the curve labeled #1 in FIG. 8 shows the input impedance for the multi-chip module embodiment of FIG. 7C. The curve labeled #2 in FIG. 8 shows the input impedance for the multi-chip module embodiment of FIG. 7B. The curve labeled #3 in FIG. 8 shows the input impedance for the multi-chip module embodiment of FIG. 7A. The curve labeled #4 in FIG. 8 shows the input impedance for a comparative example, where both the first inductor (LG) 206 and second inductor (LS) 208 are located on the first layer but with a large separation between the inductors. As can be seen in FIG. 8 (taking Z0=50 ohm) the real part of the input impedance for the embodiment of FIG. 7C is equal to 0.796*50=39.8 ohm, the real part of the input impedance for the embodiment of FIG. 7B is equal to 0.663*50=33.15 ohm, and the real part of the input impedance for the embodiment of FIG. 7A is equal to 0.59*50=29.5 ohm. For the comparative example, the real part of the input impedance is equal to only 0.558*50=27.9 ohm. Therefore in each of the embodiments of FIGS. 7A to 7C the real part of Zin is thus improved (and closer to 50 ohm) in comparison to the comparative example. The embodiment of FIG. 7C shows the most improvement, followed by the embodiment of FIG. 7B.

The MCM 500 of FIGS. 6 to 7C may be manufactured analogously to as described above for the MCM 300 of FIGS. 3 to 4D, and may include the various modifications as described above for the MCM 300 of FIGS. 3 to 4D.

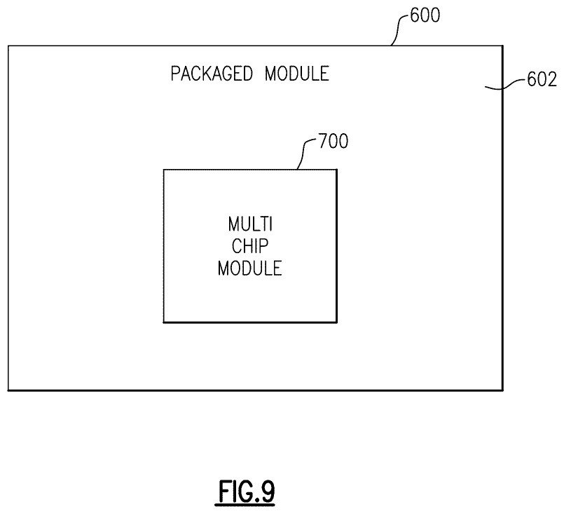

FIG. 9 shows that in some embodiments, one or more features as described herein can be implemented in a packaged module 600. Such a packaged module can include a packaging substrate 602 configured to receive a plurality of components. At least some of the components mounted on the packaging substrate 602 can include a multi-chip module 700 such as one or more of the example multi-chip module devices described herein (e.g. multi-chip modules 100, 500 or 300 of FIGS. 1, 3 and 6).

In some implementations, the packaged module 600 having one or more features described herein can be included in an RF device such as a wireless device. In some embodiments, such a wireless device can include, for example, a mobile device such as a cellular phone, a smart-phone, a hand-held wireless device with or without phone functionality, a wireless tablet, etc.

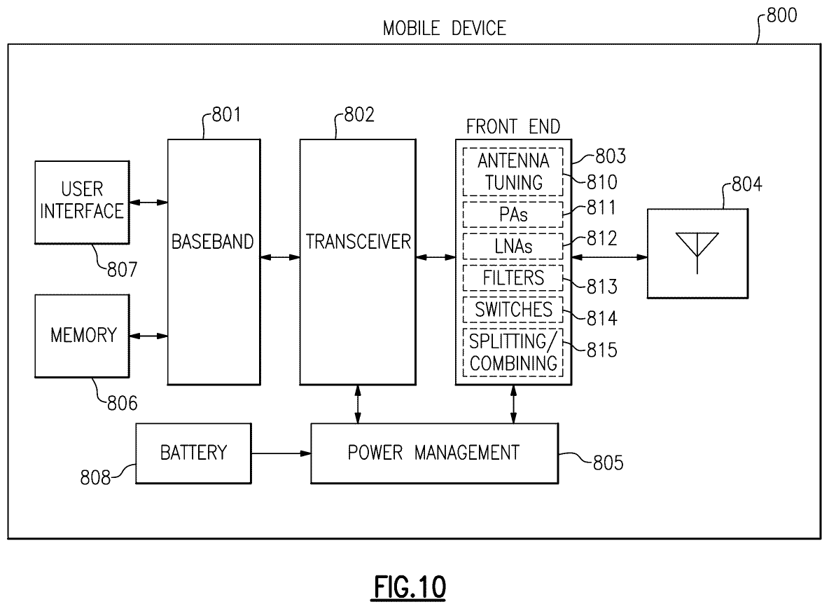

FIG. 10 is a schematic diagram of one embodiment of a mobile device 800. The mobile device 800 includes a baseband system 801, a transceiver 802, a front end system 803, antennas 804, a power management system 805, a memory 806, a user interface 807, and a battery 808.

The mobile device 800 can be used communicate using a wide variety of communications technologies, including, but not limited to, 2G, 3G, 4G (including LTE, LTE-Advanced, and LTE-Advanced Pro), 5G NR, WLAN (for instance, WiFi), WPAN (for instance, Bluetooth and ZigBee), WMAN (for instance, WiMax), and/or GPS technologies.

The transceiver 802 generates RF signals for transmission and processes incoming RF signals received from the antennas 804. It will be understood that various functionalities associated with the transmission and receiving of RF signals can be achieved by one or more components that are collectively represented in FIG. 10 as the transceiver 802. In one example, separate components (for instance, separate circuits or dies) can be provided for handling certain types of RF signals.

The front end system 803 aids in conditioning signals transmitted to and/or received from the antennas 804. In the illustrated embodiment, the front end system 803 includes antenna tuning circuitry 810, power amplifiers (PAs) 811, low noise amplifiers (LNAs) 812, filters 813, switches 814, and signal splitting/combining circuitry 815. However, other implementations are possible. The LNAs 812 can include one or more LNAs implemented in accordance with the teachings herein.

The front end system 803 can provide a number of functionalities, including, but not limited to, amplifying signals for transmission, amplifying received signals, filtering signals, switching between different bands, switching between different power modes, switching between transmission and receiving modes, duplexing of signals, multiplexing of signals (for instance, diplexing or triplexing), or some combination thereof.

In certain implementations, the mobile device 800 supports carrier aggregation, thereby providing flexibility to increase peak data rates. Carrier aggregation can be used for both Frequency Division Duplexing (FDD) and Time Division Duplexing (TDD), and may be used to aggregate a plurality of carriers or channels. Carrier aggregation includes contiguous aggregation, in which contiguous carriers within the same operating frequency band are aggregated. Carrier aggregation can also be non-contiguous, and can include carriers separated in frequency within a common band or in different bands.

The antennas 804 can include antennas used for a wide variety of types of communications. For example, the antennas 804 can include antennas for transmitting and/or receiving signals associated with a wide variety of frequencies and communications standards.

In certain implementations, the antennas 804 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The mobile device 800 can operate with beamforming in certain implementations. For example, the front end system 803 can include amplifiers having controllable gain and phase shifters having controllable phase to provide beam formation and directivity for transmission and/or reception of signals using the antennas 804. For example, in the context of signal transmission, the amplitude and phases of the transmit signals provided to the antennas 804 are controlled such that radiated signals from the antennas 804 combine using constructive and destructive interference to generate an aggregate transmit signal exhibiting beam-like qualities with more signal strength propagating in a given direction. In the context of signal reception, the amplitude and phases are controlled such that more signal energy is received when the signal is arriving to the antennas 804 from a particular direction. In certain implementations, the antennas 804 include one or more arrays of antenna elements to enhance beamforming.

The baseband system 801 is coupled to the user interface 807 to facilitate processing of various user input and output (I/O), such as voice and data. The baseband system 801 provides the transceiver 802 with digital representations of transmit signals, which the transceiver 802 processes to generate RF signals for transmission. The baseband system 801 also processes digital representations of received signals provided by the transceiver 802. As shown in FIG. 10, the baseband system 801 is coupled to the memory 806 of facilitate operation of the mobile device 800.

The memory 806 can be used for a wide variety of purposes, such as storing data and/or instructions to facilitate the operation of the mobile device 800 and/or to provide storage of user information.

The power management system 805 provides a number of power management functions of the mobile device 800. In certain implementations, the power management system 805 includes a PA supply control circuit that controls the supply voltages of the power amplifiers 811. For example, the power management system 805 can be configured to change the supply voltage(s) provided to one or more of the power amplifiers 811 to improve efficiency, such as power added efficiency (PAE).

As shown in FIG. 10, the power management system 805 receives a battery voltage from the battery 808. The battery 808 can be any suitable battery for use in the mobile device 800, including, for example, a lithium-ion battery.

The principles and advantages of the embodiments herein can be used for any other systems or apparatus that have needs for low noise amplification. Examples of such apparatus include RF communication systems. RF communications systems include, but are not limited to, mobile phones, tablets, base stations, network access points, customer-premises equipment (CPE), laptops, and wearable electronics. Thus, the low noise amplifiers herein can be included in various electronic devices, including, but not limited to, consumer electronic products.

Having described above several aspects of at least one embodiment, it is to be appreciated various alterations, modifications, and improvements will readily occur to those skilled in the art. Such alterations, modifications, and improvements are intended to be part of this disclosure and are intended to be within the scope of the invention. Accordingly, the foregoing description and drawings are by way of example only, and the scope of the invention should be determined from proper construction of the appended claims, and their equivalents.

1. A multi-chip module comprising:
a plurality of layers including a first layer, a second layer and a third layer, said second layer positioned between the first layer and third layer;
a low noise amplifier circuit distributed across the plurality of layers and including a first inductor in the first layer, a second inductor in the third layer, and a transistor;
a common ground plane spanning over at least a portion of the second layer; and
a dielectric opening through the common ground plane, said dielectric opening located between the first inductor and the second inductor.

2. The multi-chip module of claim 1 wherein the first inductor is connected to a gate terminal or base terminal of the transistor.

3. The multi-chip module of claim 1 wherein the second inductor is connected to a source terminal or emitter terminal of the transistor.

4. The multi-chip module of claim 1 wherein the transistor is implemented within an integrated circuit in the multi-chip module.

5. The multi-chip module of claim 1 wherein the first inductor is a surface-mount device.

6. The multi-chip module of claim 1 wherein the second inductor is formed from a signal trace in the third layer.

7. The multi-chip module of claim 1 wherein the common ground plane is formed from a sheet of conductive material such as a metal.

8. The multi-chip module of claim 1 wherein each of the first layer, second layer and third layer include a conductive sublayer and a dielectric sublayer, and the common ground plane is formed from a portion of the conductive sublayer of the second layer.

9. The multi-chip module of claim 1 wherein the dielectric opening overlaps at least a portion of the first inductor when viewed from a direction perpendicular to the plurality of layers.

10. The multi-chip module of claim 1 wherein the dielectric opening overlaps at least a portion of the second inductor when viewed from a direction perpendicular to the plurality of layers.

11. The multi-chip module of claim 1 further comprising an additional common ground plane spanning over at least a portion of the third layer.

12. The multi-chip module of claim 11 further comprising an additional dielectric opening through the additional common ground plane, said additional dielectric opening located between the first inductor and the second inductor.

13. The multi-chip module of claim 12 wherein the additional dielectric opening is positioned adjacent to the second inductor in the third layer.

14. The multi-chip module of claim 12 wherein the additional dielectric opening overlaps at least a portion of the first inductor when viewed from a direction perpendicular to the plurality of layers.

15. The multi-chip module of claim 1 further comprising a fourth layer, with the third layer positioned between the second layer and the fourth layer, and the second inductor is included in both the third layer and the fourth layer.

16. The multi-chip module of claim 15 wherein the second inductor is formed from signal traces on both the third layer and the fourth layer.

17. The multi-chip module of claim 1 wherein the low noise amplifier circuit is a single-stage or multi-stage amplifier including a common-source or common-emitter amplifier stage.

18. The multi-chip module of claim 1 wherein the dielectric opening is configured to increase mutual inductance between the first inductor and second inductor.

19. A packaged module comprising:
a packaging substrate; and
a multi-chip module mounted on the packaging substrate, the multi-chip module including a plurality of layers including a first layer, a second layer and a third layer, said second layer positioned between the first layer and third layer; a low noise amplifier circuit distributed across the plurality of layers and including a first inductor in the first layer, a second inductor in the third layer, and a transistor; a common ground plane spanning over at least a portion of the second layer; and a dielectric opening through the common ground plane, said dielectric opening located between the first inductor and the second inductor.

20. A wireless device comprising:
an antenna configured to receive a radio frequency signal;
a front end module in communication with the antenna, the front end module including a multi-chip module including a plurality of layers including a first layer, a second layer and a third layer, said second layer positioned between the first layer and third layer; a low noise amplifier circuit distributed across the plurality of layers and including a first inductor in the first layer, a second inductor in the third layer, and a transistor; a common ground plane spanning over at least a portion of the second layer; and a dielectric opening through the common ground plane, said dielectric opening located between the first inductor and the second inductor; and
a transceiver in communication with the front end module.
